(19) United States
(12) Patent Application Publication
(10) Pub. No.: US 2005/0084984 A1
(43) Pub. Date: Apr. 21, 2005

(54) Method for forming ferrocapacitors and FeRAM devices

(76) Inventors: Haoren Zhuang, New York, NY (US); Rainer Bruchhaus, Kanagawa-ken (JP); Ulrich Egger, Kanagawa-ken (JP); Jenny Lian, New York, NY (US); Nicolas Nagel, Kanagawa-ken (JP)

Correspondence Address: FISH & RICHARDSON, PC, 12390 EL CAMINO REAL, SAN DIEGO, CA, 92130-2081, US

(21) Appl. No.: 10/678,952

(22) Filed: Oct. 2, 2003

(51) Int. Cl. H01L 31/119

(52) U.S. Cl. 438/3

(57) ABSTRACT

A vertical capacitor of an FeRAM device is formed by depositing conductive material and etching it to form electrodes, which are located over openings in an insulating layer so that they are electrically connected to lower levels of the structure. A layer of ferroelectric material is formed on the sides of the electrodes, and etched to a desired, uniform thickness. Conductive material is deposited over the ferroelectric material to form a uniform surface onto which another insulating layer can be deposited. Since this process does not include etching of an insulating layer at a time between the formation of the electrodes and the deposition of the ferroelectric material, no fences of insulating material are formed between them. The geometry can be accurately controlled, to give uniform electric fields and reliable operating parameters.

### FIELD OF THE INVENTION

The present invention relates to methods for forming ferrocapacitors of the kind used in FeRAM devices, and to methods for forming FeRAM devices themselves. The invention further relates to FeRAM devices including ferrocapacitors formed by the method.

### BACKGROUND OF INVENTION

Many conventional FeRAM devices include a horizontal ferrocapacitor structure, in which a stack of layers is formed including top and bottom electrodes sandwiching a ferroelectric layer. An alternative “vertical capacitor” structure was suggested in U.S. Pat. No. 6,300,652, the disclosure of which is incorporated herein by reference. A vertical capacitor includes a ferroelectric element sandwiched between electrodes to either side, all at substantially the same level in the FeRAM device.

The process steps of a conventional technique for forming a vertical capacitor structure are illustrated in FIGS. 1 to 5. The vertical capacitors are typically to be formed over a substructure, which may for example be of the form shown in FIG. 1 in which various electronic components 1 are connected to conductive plugs 3 which extend upwards through a matrix 5 (e.g. of TEOS (tetraethylorthosilicate)). The upper ends of the plugs 3 terminate In TiN/Ir barrier elements 7, having a top surface flush with the surface of the matrix 5.

As shown in FIG. 2, an insulating layer 9 of Al₂O₃ is formed over the surface of the matrix 5, and a thicker layer of ferroelectric material 11 such as PZT (PbZrTiO₃) Is formed over that.

As shown in FIG. 3, hardmask elements 13 are deposited over selected areas of the PZT layer 11, and the portions of the PZT 11 and Al₂O₃ 9 which are not protected by the hardmask elements 13 are etched all the way through, forming openings 17. During this process Al₂O₃ fences 15 are often formed on the sides of the remaining PZT 11.

The openings 17 are then filled with conductive material 19 such as IrO₂, by depositing IrO₂ over the entire structure, as shown in FIG. 4, and chemical-mechanical planarization (CMP) polishing is performed to form a flat upper surface 21 which is partly the PZT 11 and partly the conductive material 19. Then, as shown in FIG. 5, an Al₂O₃ layer 23 is formed over the surface 19. The elements 19 of IrO₂ constitute electrodes, while the remaining PZT 11 forms the dielectric.

The vertical capacitor structure has great potential for reducing the cell size, especially if the etching taper angle of the remaining PZT 11 (i.e. the angle between the horizontal direction and the sides of the remaining PZT 11) is high. However, if the taper angle becomes close to 90°, the Al₂O₃ fences 15 are more likely to be formed. These fences 15 are difficult to remove (e.g. by a wet cleaning process), and dramatically reduce the Q_{SW} (i.e. the maximum charge which can be stored in the ferrocapacitor) because the insulating fences 15 reduce the effective area of the capacitor.

Another reason for wanting to achieve a high taper angle is because it increases the uniformity of the electric field in the ferrocapacitor. If the ferroelectric dielectric is thinner in its upper portion than in its lower portion then the electric field will be higher at the top of the ferrocapacitor than at the bottom. The lack of electric field uniformity can cause problems for drive voltage setting, and device operation abnormalities. For example, the upper part of the dielectric has to work at a higher electric field than necessary.

These problems would be reduced by increasing the taper angle to be very close to 90°, but as mentioned above this leads to thicker fences.

### SUMMARY OF THE INVENTION

The present invention aims to alleviate the above problem, at least partially, and in particular to provide a new and useful method for forming ferrocapacitors and FeRAM devices with improved properties.

In general terms, the present invention proposes that, rather than forming the electrodes in holes formed in the ferroelectric material, the electrodes should be formed over openings in the insulating layer before the ferroelectric material is deposited.

Thus, no step of etching the insulating layer is required after the interface between the electrodes and ferroelectric material is formed. Accordingly, the fence problem is removed.

Furthermore, the ferroelectric material is preferably formed as a layer on the sides of the electrodes, rather than to fill the gaps between the electrodes. This means that the thickness of the ferroelectric material is not determined by the geometry of the gaps between the electrodes. This means that the thickness of the capacitor dielectric can be controlled very accurately, which in turn makes it easier to ensure that the electric field across it is uniform. Furthermore, the thickness of the ferroelectric layer can be selected to match a desired drive voltage.

Preferably, the thickness of the ferroelectric layer is optimised (e.g. made more uniform on the sides of the electrode, or its thickness there reduced to a desired lower value) by a further etching step performed on it.

Optionally, the further etching step may remove portions of the ferroelectric material extending over the insulating layer.

The ferroelectric layer is preferably covered with a support material, so as to fill the gaps between the electrodes and form an even surface. The support material used to cover the ferroelectric material is preferably a conductive material (e.g. irdinium), which, according to what other components it is attached to, may act as a dummy electrode. Alternatively, the ferroelectric material may be at least partly covered by an insulating material (such as TEOS).

Optionally, a conductive material (e.g. platinum) may be deposited on the sides of the electrodes, between the electrodes and the ferroelectric material. Similarly, a layer of conductive material may be deposited on the side of the ferroelectric layer away from the electrode.

Specifically, one expression of the invention is a method for forming a ferrocapacitor comprising:
forming electrode elements over a substructure, the electrode elements being in electrical contact with electrically conductive elements extending into the substructure; and
depositing ferroelectric material between the electrode elements.

An alternative expression of the invention is an FeRAM device comprising electrode elements and ferroelectric elements, the electrode elements and ferroelectric elements being formed over a substructure, the electrodes being in electrical contact with electrically conductive elements extending into the substructure and the ferroelectric elements being arranged between the electrodes as layers formed on the lateral sides of the electrodes.

### BRIEF DESCRIPTION OF THE FIGURES

Preferred features of the invention will now be described, for the sake of illustration only, with reference to the following figures in which:

FIGS. 1 to 5 show the steps of a conventional method of forming vertical capacitors;

FIGS. 6 to 10 show the steps of a method which is an embodiment of the invention; and

FIGS. 11 to 13 show ferroelectric capacitors which are alternative embodiments of the invention.

### DETAILED DESCRIPTION OF THE EMBODIMENTS

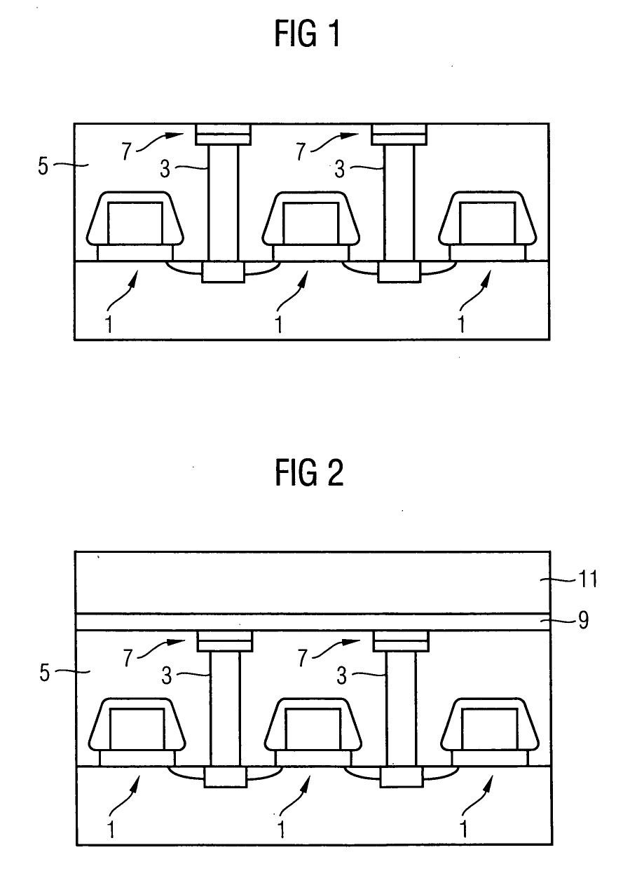

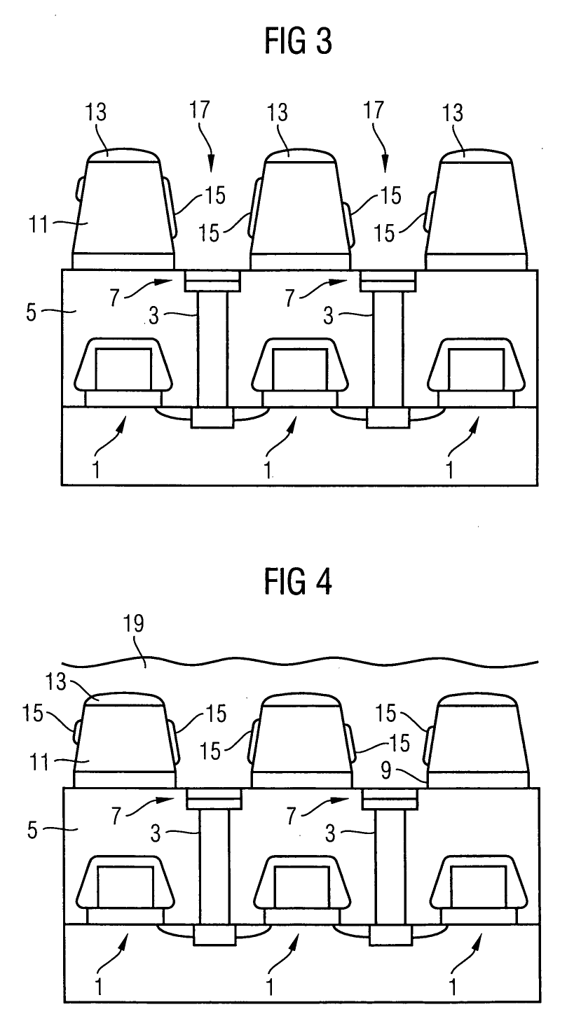

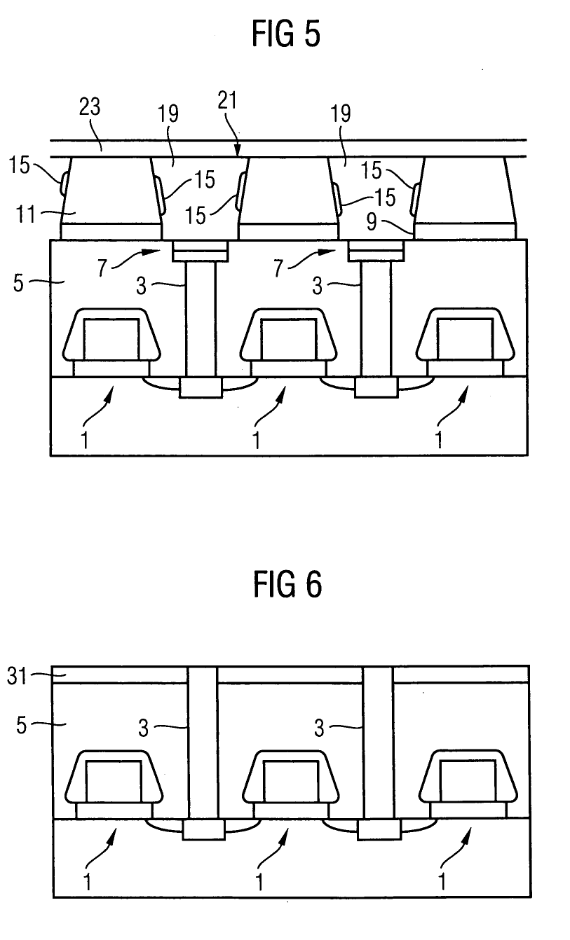

The method which is an embodiment of the invention will be explained with reference to FIGS. 6 to 11. The vertical capacitor structure is formed in these figures over a substructure which is like the one shown in FIG. 1 except that the plugs 3 and barrier elements 7 have not been formed in the matrix 5. Elements shown in FIGS. 1 to 5 which exactly correspond to elements in FIGS. 6 to 11 are Illustrated by the same reference numerals.

The first step of the method, as in the conventional method, is for an insulating layer 31 of Al₂O₃ to be formed over the substructure. Then an etching step is performed to produce openings in the matrix 5 and in insulating layer 31. The plugs 3 are then formed in these openings extending through the matrix 5 and insulating layer 31, as shown in FIG. 6.

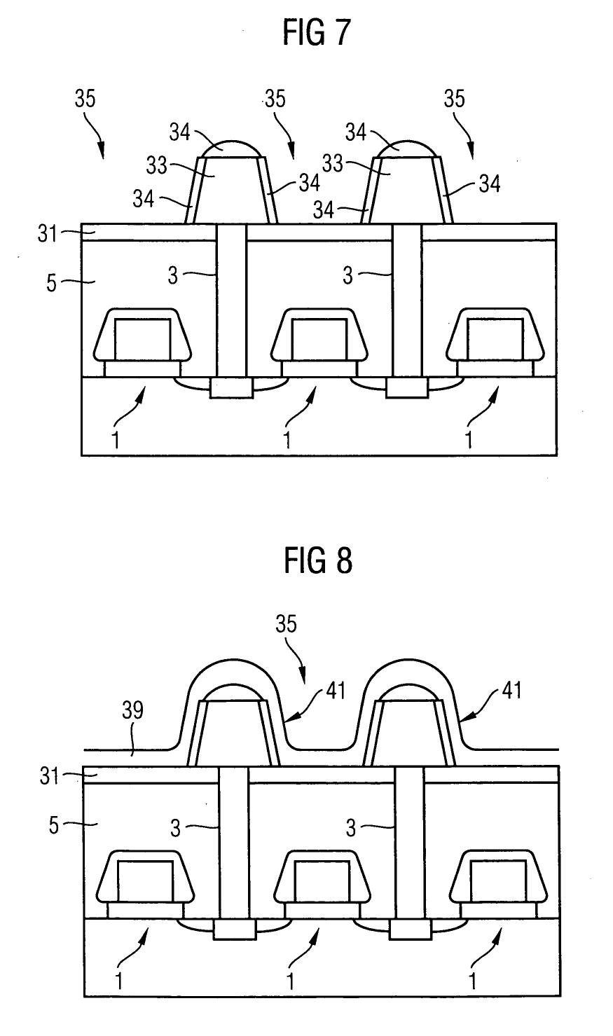

In a second step of the method, a layer 33 of conductive material (typically Iridium) is formed over the Al₂O₃ layer 31. Hardmask elements 34 are formed over conductiv layer 33, substantially above the plugs 3. These hardmask elements 34 are formed by a process in which a hardmask (TEOS) layer is formed over the conductive layer 33, then a resist layer is formed over the TEOS layer, then a lithographic process is performed, then a harmmask open (oxide RIE) process, and finally an ashing process. Although only two such elements 34 are shown in FIG. 7, it is to be understood that the structure shown in FIG. 7 is only a portion of a complete structure which extends to either side of the part shown in FIG. 7, with a periodicity equal to the spacing of the hardmask elements 34. The hardmask elements 34 may, as viewed from above, be for example square or rectangular areas, or they may be a layer containing gaps of any of these shapes. Etching is carried out using the hardmask elements 34 to form openings 35 in the conductive layer 33. In the openings 35, the entire thickness of the conductive layer 33 is preferably completely removed (and optionally also an upper part of the layer 31). A thin layer 34 (typically in the range 1 nm to 15 nm) of IrO₂ is then formed over the sides of the remaining portions of the conductive layer 33 by RTO (rapid thermal oxidation) in an atmosphere containing oxygen, to give the structure shown in FIG. 7. The IrO₂ improves the crystallinity of the capacitor.

As shown in FIG. 8, a layer 39 of a ferroelectric material, e.g. PZT, is then formed over the structure of FIG. 7, including in particular portions 41 on the sides of the openings. The portions 41 will constitute the dielectric elements in the completed ferrocapacitor device, as explained below. The thickness of the layer 39 would typically be In the range 20 nm to 200 nm.

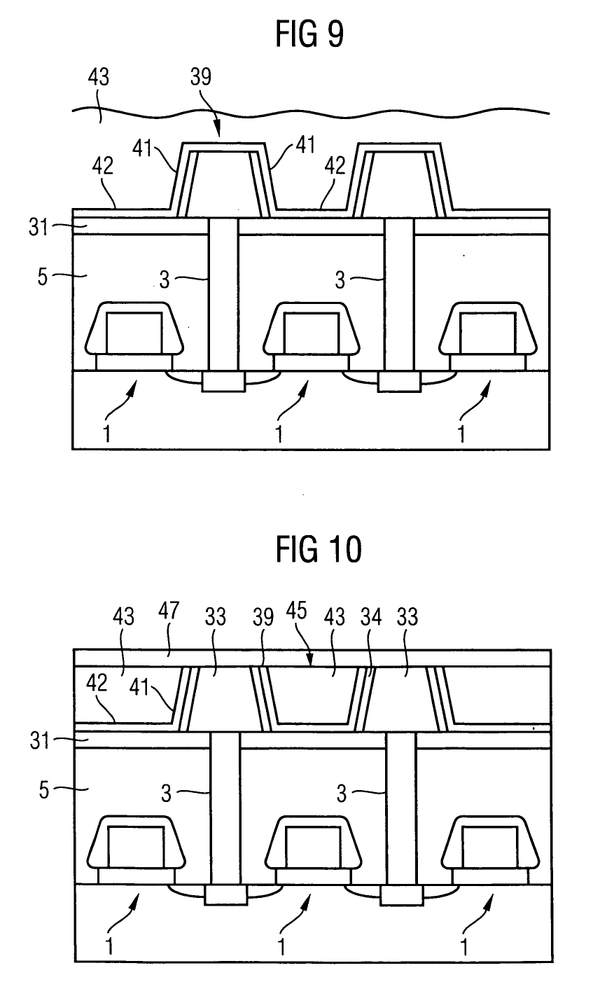

Further etching is then performed to reduce the thickness of the ferroelectric layer 39, while still leaving a film 42 of ferroelectric material extending across the insulating layer 31. Then, as shown in FIG. 9, the openings 35 are filled with support material 43, which may be a conductive material such as IrO₂.

Then, CMP polishing is performed to form a flat upper surface 45 which is partly the PZT 39, partly the conductive material 33, partly the conductive material 34, and partly the conductive support material 43. Then, an Al₂O₃ layer 47 is formed over the surface 45, to form the completed structure shown in FIG. 10. The conductive material 33 makes electrical contact with the plugs 3, thereby electrically connecting the electrodes 33 with desired electrical components of the substructure. The conductive material 43 acts as a dummy electrode.

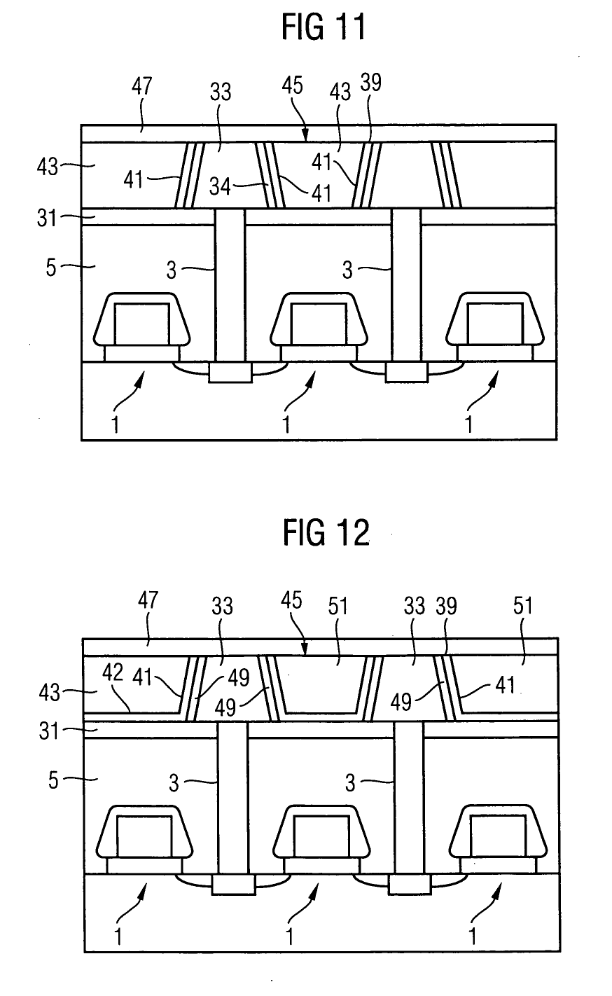

Although only a single embodiment of the invention has been described in detail above, many variations of the method are possible within the scope of the invention as will be clear to a skilled reader. For example, three alternative structures which can be formed according to the invention are shown in FIGS. 11 to 13 respectively. Elements of these figures which correspond exactly to elements of FIGS. 6 to 10 are indicated by the same reference numerals.

Firstly, as shown in FIG. 11, the etching step which is performed between FIGS. 8 and 9 above may be continued to the point that the layer 42 extending over the insulating layer 31 is completely removed. This would have the advantage of making makes the electric field more uniform at the edges of the layers 41.

Secondly, layers of Pt may be included in the structure. For example, a Pt layer 49 can be provided between the conductive elements 33 and the portions 41 of the PZT layer 39, instead of or In addition to the layer 32. Another Pt layer could be between the PZT 39 and the conductive material 43, or may indeed replace the material 43 as shown in FIG. 12, which has a layer 49 of PZT in place of the layer 32 and in which the opening in the PZT is filled with Pt 51. The possibility of Introducing Pt In this way may be useful for increasing the options available to the designer of the system, since the Pt can significantly modify the characteristics of the capacitor.

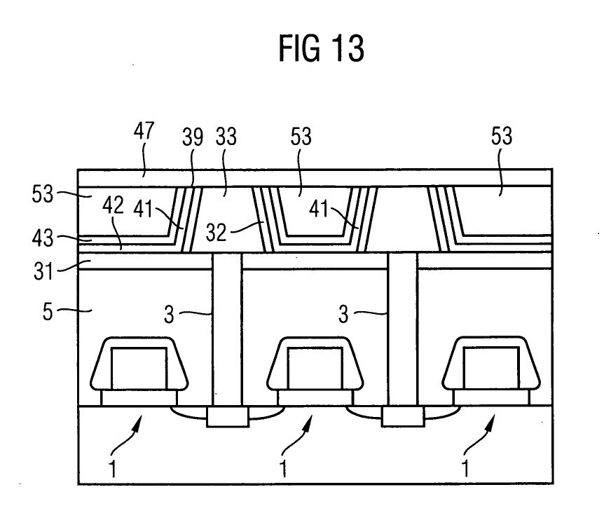

Thirdly, the conductive material 43 (or the Pt which replaces it in FIG. 12), may contain an element 53 of non-conductive material (e.g. of TEOS), as shown in FIG. 13. Such a material does no harm, since only the part of the conductive material 43 near the PZT 39 plays any active role. The use of TEOS in this way is beneficial since it is a relatively low-cost material, the dummy electrode performance may be improved, and the ferroelectric device is provided with a more effective cover.

These three variations are combinable in any combination within the scope of the invention.

1. A method for forming a ferrocapacitor comprising:
forming electrode elements over a substructure, the electrode elements being in electrical contact with electrically conductive elements extending into the substructure; and
depositing ferroelectric material between the electrode elements.

2. A method according to claim 1 in which the ferroelectric material is formed as a layer covering the sides of the electrode elements, the method further including a step of depositing support material over the ferroelectric layer to fill gaps between the electrode elements.

3. A method according to claim 2 in which the layer of ferroelectric material is formed by depositing ferroelectric material and then etching it to reduce its thickness.

4. A method according to claim 2 in which the support material comprises electrically conductive material at least at an interface between the support material and the ferroelectric material.

5. A method according to claim 1 in which the electrode elements are formed over an insulating layer containing openings, the electrodes contacting the electrically conductive elements of the substructure through the openings.

6. A ferrocapacitor device formed by a method according to claim 1.

7. An FeRAM device Including at least one ferrocapacitor formed by a method according to claim 1.

8. An FeRAM device comprising electrode elements and ferroelectric elements, the electrode elements and ferroelectric elements being form d over a substructure, the electrodes being in electrical contact with electrically conductive elements extending into the substructure and the ferroelectric elements being arranged between the electrodes as layers formed on the lateral sides of the electrodes.
